(19) United States
(12) Patent Application Publication
(10) Pub. No.: US 2013/0286295 A1
(43) Pub. Date: Oct. 31, 2013

(54) TELEVISION RECEIVER AND ELECTRONIC DEVICE

(71) Applicant: KABUSHIKI KAISHA TOSHIBA, Tokyo (JP)

(72) Inventors: Issei Takahashi, Tokyo (JP); Tomofumi Miyamoto, Tokyo (JP); Toshikatsu Nakamura, Tokyo (JP)

(73) Assignee: KABUSHIKI KAISHA TOSHIBA, Tokyo (JP)

(21) Appl. No.: 13/706,031

(22) Filed: Dec. 5, 2012

(30) Foreign Application Priority Data
Apr. 25, 2012 (JP) 2012-100272

(51) Int. Cl. H04N 5/655; H05K 7/14

(52) U.S. Cl. CPC H04N 5/655; H05K 7/1427
USPC 348/836; 361/752

(57) ABSTRACT

According to at least one embodiment, a television receiver includes: a display; a casing comprising an opening, the casing being configured house the display; a board configured to be housed in the casing; a connector configured to be mounted on the board and exposed from the opening; an elastic member between the connector and the casing, the elastic member being configured to touch the connector; a cover configured to be at least partially positioned at a side of the connector opposite to the elastic member and cover a part of the connector; and a restriction portion configured to be positioned at the side of the connector opposite to the elastic member and restrict movement of the connector.

### CROSS-REFERENCE TO RELATED APPLICATIONS

This application is based upon and claims the benefit of priority from Japanese Patent Application No. 2012-100272, filed on Apr. 25, 2012, the entire contents of which are incorporated herein by reference.

### FIELD

Embodiments described herein relate generally to a television receiver and an electronic device.

### BACKGROUND

Conventionally, there has been known an electronic device such that a connector and a casing are electrically connected with each other by means of an elastic body provided between the connector and the casing to establish a ground for the connector.

However, in the electronic device such as a conventional television receiver, the connector is pressed by the elastic body and hence, there exists a possibility that the position of the connector is displaced.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view illustrating an example of a television receiver according to a first embodiment as viewed from the front side of the television receiver;

FIG. 2 is an exemplary perspective view illustrating an example of the television receiver in the first embodiment as viewed from the lateral side of the television receiver;

FIG. 3 is an exemplary cross-sectional view taken along a line in FIG. 1;

FIG. 4 is an exemplary cross-sectional view illustrating a part of an example of a television receiver according to a first modification of the first embodiment;

FIG. 5 is an exemplary cross-sectional view illustrating a part of an example of a television receiver according to a second modification of the first embodiment;

FIG. 6 is an exemplary perspective view illustrating an example of a television receiver according to a second embodiment in an open state;

FIG. 7 is an exemplary plan view illustrating an example of the electronic device in the second embodiment in a folded state;

FIG. 8 is an exemplary side view illustrating an example of the electronic device in the second embodiment in the folded state;

FIG. 9 is an exemplary cross-sectional view taken along a line IX-IX in FIG. 8;

FIG. 10 is an exemplary perspective view illustrating a part of an example of the electronic device in the second embodiment;

FIG. 11 is an exemplary perspective view illustrating a part of an example of the electronic device in the second embodiment and an exemplary view illustrating a state that a harness is removed from the electronic device in a state illustrated in FIG. 10;

FIG. 12 is an exemplary perspective view illustrating a part of an example of the electronic device in the second embodiment and an exemplary view illustrating a state that a board is removed from the electronic device in a state illustrated in FIG. 11;

FIG. 13 is an exemplary perspective view illustrating a part of an example of the electronic device in the second embodiment and an exemplary view illustrating a state that a connector cap is removed from the electronic device in a state illustrated in FIG. 12;

FIG. 14 is an exemplary perspective view illustrating the connector cap of an example of the electronic device in the second embodiment; and

FIG. 15 is an exemplary perspective view illustrating a connector cap of an example of an electronic device according to a modification of the second embodiment.

### DETAILED DESCRIPTION

In general, according to one embodiment, A television receiver comprises: a display; a casing comprising an opening, the casing being configured to house the display; a board configured to be housed in the casing; a connector configured to be mounted on the board and exposed from the opening; an elastic member between the connector and the casing, the elastic member being configured to touch the connector; a cover configured to be at least partially positioned at a side of the connector opposite to the elastic member and cover a part of the connector; and a restriction portion configured to be positioned at the side of the connector opposite to the elastic member and restrict movement of the connector.

A plurality of exemplary embodiments and modifications that will be explained hereinafter comprise parts having identical functions. These parts having identical functions are given the same numerals and their repeated explanations are omitted.

In each of the following embodiments, while a case that an electronic device is constituted as a television receiver or a so-called notebook type personal computer is exemplified, an electronic device according to the present embodiment is not limited thereto. The electronic device in the present embodiment can be, for example, constituted as an electronic device comprising connectors, such as a smart television system, a mobile phone, a video display device, or a video phone.

### First Embodiment

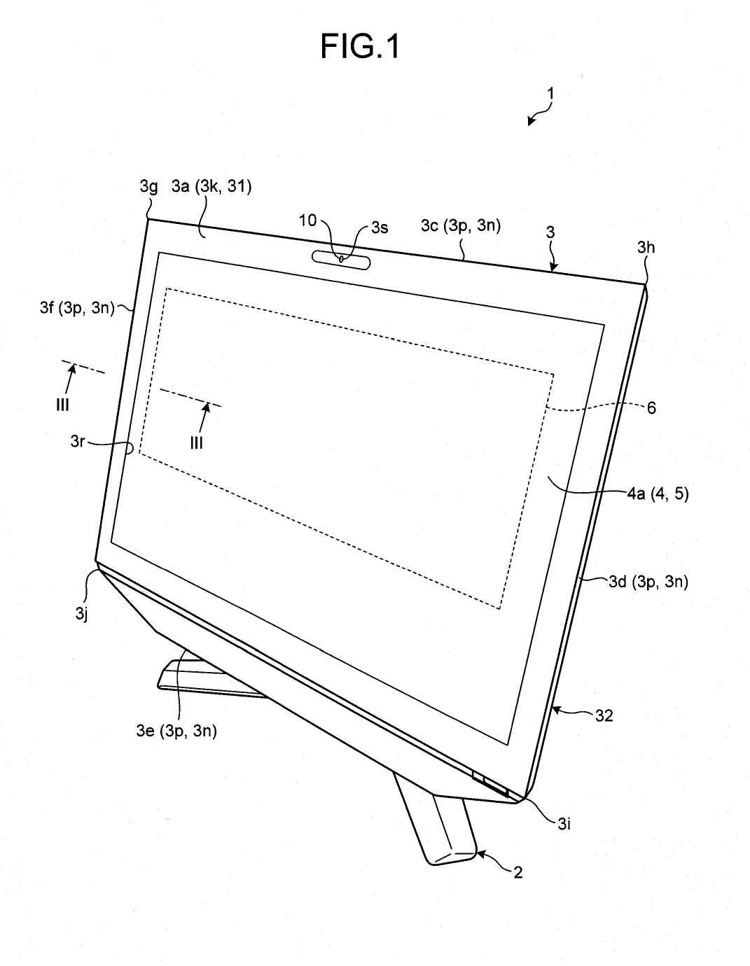

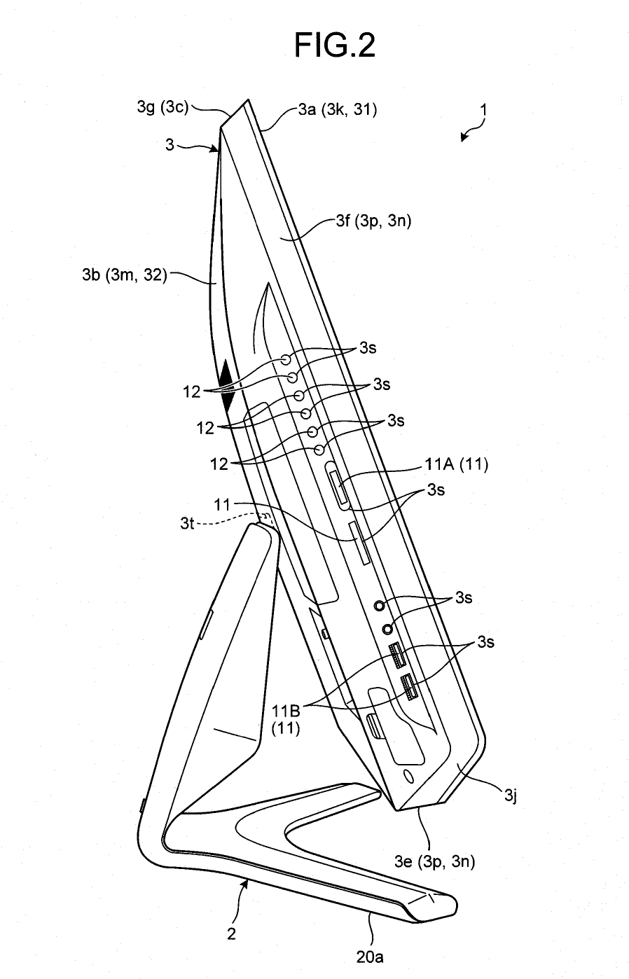

In the present embodiment, as an example illustrated in FIGS. 1 and 2, a television receiver 1 comprises a support 2 and a casing 3. To be more specific, the casing 3 (the first casing, the first part, the first component) houses at least a part of a display 4. The support 2 (the stand, the base, the support base, the second casing, the second part, the other part, the other component) supports the casing 3. The support 2 comprises an area 20a (a bottom wall, a wall, an area, a part, a rubber foot, a foot) that faces, when the support 2 is mounted on an external mounting surface (a surface, a horizontal surface), the external mounting surface in an opposed manner.

Furthermore, in the present embodiment, as an example, the support 2 supports the casing 3 by way of a hinge portion (a connecting portion, a joint portion, a rotatably supporting portion, a hinge mechanism, a connecting mechanism, a joint mechanism, a rotatably supporting mechanism) in a rotatable manner. That is, the hinge portion connects (joins) the support 2 and the casing 3 in a rotatable manner. In the present embodiment, as an example, the hinge portion changes an angle of a screen 4a in the vertical direction. That is, the hinge portion is capable of adjusting a tilting position. Here, the support 2 can support the casing 3 so that the casing can be rotated (pivoted, swiveled, for example) in other directions.

In the present embodiment, as an example illustrated in FIG. 1, the casing 3 of the television receiver 1 is formed in a quadrangular shape (a rectangular shape, as an example in the present embodiment) as viewed in a front view and a rear view. Furthermore, the casing 3 is, as an example illustrated in FIG. 2, formed in a flat rectangular parallelepiped shape with a small thickness in the front-back direction. The casing 3 comprises a surface 3a (an anterior face, a front face, a first surface, a first surface portion) and a surface 3b (a rear face, a back face, a second surface, a second surface portion) opposite to the surface 3a. The surface 3a and the surface 3b are arranged substantially parallel to each other. Furthermore, the casing 3 comprises, as illustrated in FIG. 1, four end portions 3c to 3f (side portions, edge portions) and four corner portions 3g to 3j (convex portions, bent portions, end portions). Each of the end portions 3c and 3e is an example of a width side portion. Each of the end portions 3d and 3f is an example of a length side portion.

The casing 3 comprises a wall portion 3k (a first portion, a plate, a frame, an anterior wall portion, a front wall portion, a top wall portion) comprising the surface 3a and a wall portion 3m (a second portion, a plate, a rear wall portion, a back wall portion, a bottom wall portion, see FIG. 2) comprising the surface 3b. The wall portions 3k and 3m are formed in a quadrangular shape (a rectangular shape, as an example in the present embodiment). Furthermore, the casing 3 comprises four wall portions 3n (third portions, plates, side wall portions, end wall portions, erected wall portions, connecting portions) comprising surfaces 3p (side surfaces, peripheral surfaces, third surfaces) each of which extends between the wall portion 3k and the wall portion 3m. Here, the wall portion 3k is, as an example, provided with an opening 3r formed in a quadrangular shape. Accordingly, the wall portion 3k is formed in a quadrangular shape and in a frame shape.

Furthermore, the casing 3 can be constituted of a plurality of parts (separated bodies) combined with each other. In the present embodiment, the casing 3 comprises, as an example, a first casing member 31 (a first portion, a front side member, a mask, a mask portion, a cover, a front cover, a cover portion, a first region) comprising at least the wall portion 3k and a second casing member 32 (a second portion, a rear side member, a base, a base portion, a bottom, a bottom portion, a cover, a rear cover, a cover portion, a second region) comprising at least the wall portion 3m. The wall portions 3n are comprised in at least any one of the first casing member 31 and the second casing member 32 (the second casing member 32, for example). Furthermore, the casing 3 can comprise, in addition to the first casing member 31 and the second casing member 32, a third casing member (a third portion, an intermediate portion, a spacer member, a barrier member, a wall member, an interjacent member, an inner plate, a middle plate, a middle frame, a third region, not illustrated in the drawings), a fourth casing member (a fourth portion, an intermediate portion, a spacer member, a barrier member, a wall member, an interjacent member, a cover, a shield, a fourth region, not illustrated in the drawings), or other members that are positioned therebetween.

The casing 3 can be made of metallic, synthetic-resin, or other material. The first casing member 31 and the second casing member 32 can be made of a material being comparatively low in rigidity (a material being lower in rigidity than that of the third casing member or the fourth casing member; that is, a synthetic-resin material, for example). Here, wall portions such as ribs (protruding portions, protruding wall portions, not illustrated in the drawings) can be provided on sides of the first casing member 31 and the second casing member 32, the sides facing inside the casing 3. The wall portions easily increase the rigidity of the casing 3.

In the present embodiment, as an example illustrated in FIG. 2, the surface 3b, the surface 3p, or other portions of the casing 3 can be provided with connectors 11, operation modules 12, or the like. Examples of the connectors 11 include a connector 11A for data communication, a universal serial bus (USB) connector 11B, a connector for a power cable, a card connector, and a connector for an earphone or a microphone. Examples of the operation modules 12 include push buttons, push switches, slide switches, pointing devices, and dials. Furthermore, as illustrated in FIG. 1, the surface 3a can be provided with a camera module 10 (a camera, an image pickup device). The connectors 11, the operation modules 12, and the camera module 10, for example, are exposed from openings 3s provided in the wall portions 3k, 3m, and 3n.

In the present embodiment, as an example illustrated in FIG. 1, the screen 4a positioned at the surface 3a side of the display 4 (the display part, the display unit, the display panel) is exposed toward the front side (outside) of the casing 3 through the opening 3r. A user can view the screen 4a through the opening 3r from the front side of the casing 3. The display 4 is formed in a quadrangular shape (a rectangular shape, as an example in the present embodiment) as viewed in a front view. Furthermore, the display 4 is formed in a flat rectangular parallelepiped shape with a small thickness in the front-back direction. The display 4 is, for example, constituted of a liquid crystal display (LCD), an organic electro-luminescent display (OELD), or the like.

In the present embodiment, as an example, the display 4 provides an input operation panel 5 (a touch panel, a touch sensor, or an operation panel, as an example) on the front side (the face side, the wall portion 3k side) thereof. The input operation panel 5 is formed in a transparent flat rectangular parallelepiped shape with a comparatively small thickness and covers the screen 4a. An operator (a user, for example) performs, for example, operations of touching, pushing, or rubbing the input operation panel 5 by using a finger or a tool (a stylus or the like, not illustrated in the drawings), or operations of moving the finger or the stylus in the vicinity of the input operation panel 5 thus performing input processing. Furthermore, light emitted from the screen 4a of the display 4 passes through the input operation panel 5 and goes out from the opening 3r of the wall portion 3k toward the front side of the casing 3. The input operation panel 5 is an example of an input module.

In the present embodiment, as an example illustrated in FIG. 1, the casing 3 houses therein one or more boards 6 (a circuit board, a control board, a main board, an electric component, a first electric component) on the rear side of the display 4 (on the reverse side, the back side, or the wall portion 3m side of the display 4, on a side opposite to the display 4). The board 6 is provided parallel to the display 4. The board 6 is provided in a state that the board 6 is spaced apart from the wall portions 3k, 3m, and 3n, for example; that is, in a state that a space (a clearance) is formed between the board 6 and the wall portions 3k, 3m, and 3n, for example.

In the present embodiment, as an example, the board 6 can, for example, mount thereon a plurality of parts (not illustrated in the drawings) such as a central processing unit (CPU), a graphics controller, a power circuit component, a platform controller hub (PCH), a memory slot connector, an LCD connector, an input/output (I/O) connector, a power supply coil, an element, or a connector. The board 6 mounts the connector 11A for data communication thereon. Furthermore, a control circuit can, for example, comprise a video signal processing circuit, a tuner, a high-definition multi media interface (HDMI) signal processing circuit, an audio video (AV) input terminal, a remote control signal receiving module, a control module, a selector, an onscreen display interface, a storage (a read only memory (ROM), a random access memory (RAM), a hard disk drive (HDD), or a solid state drive (SSD), for example), and an audio signal processing circuit. The control circuit controls the output of videos (moving pictures, still pictures, for example) on the screen 4a of the display 4, the output of sounds by a speaker (not illustrated in the drawings), the emission of light from a light emitting diode (LED, not illustrated in the drawings), for example. The display 4, the speaker, and the LED, are examples of an output module.

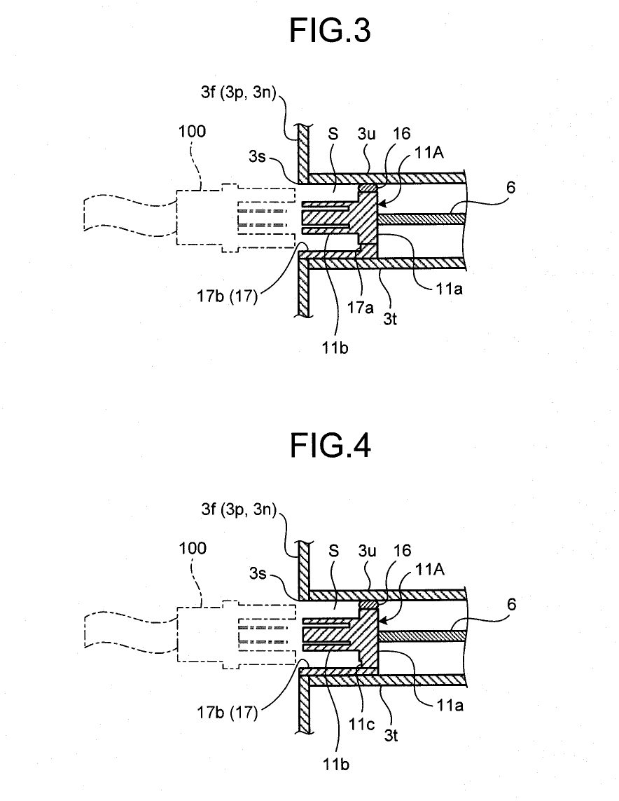

Furthermore, in the present embodiment, as an example illustrated in FIG. 3, the connector 11A is arranged between a wall portion 3t (a first wall portion) and a wall portion 3u (a second wall portion) of the casing 3 and exposed from the opening 3s. The wall portions 3t and 3u are, for example, provided in an extending manner from the inner surface of the wall portion 3n toward the inside of the casing 3. The wall portions 3t and 3u are arranged so that the wall portions 3t and 3u overlaps with each other in the front-back direction. The connector 11A comprises a base portion 11a and an attachment portion 11b. The base portion 11a is, as an example, formed in a substantially rectangular parallelepiped shape. The base portion 11a is housed in the inside of the casing 3. The attachment portion 11b extends from the base portion 11a toward the outside of the casing 3. The attachment portion 11b extends from the base portion 11a toward the opening 3s. In the connector 11A, an external connector 100 is attached to the attachment portion 11b. A space S for inserting the external connector 100 is formed around the attachment portion 11b.

In between the connector 11A and the wall portion 3u of the casing 3, an elastic member 16 (an elastic part, a gasket) is positioned. The elastic member 16 has elasticity. The elastic member 16 is, as an example, adhered (fixed) to the wall portion 3u by bonding, for example. The elastic member 16 abuts on (touches) the base portion 11a of the connector 11A to elastically support the connector 11A. Furthermore, the elastic member 16 is made of a conductive material. The elastic member 16 connects the connector 11A and the wall portion 3u electrically to establish a ground for the connector 11A.

Furthermore, a connector cap 17 (a cover, a part, a cap) is provided to the side of the connector 11A opposite to the elastic member 16. The connector cap 17 constitutes a part of the casing 3. At least a part of the connector cap 17 is positioned at the side of the connector 11A opposite to the elastic member 16 and covers a part of the connector 11A. The connector cap 17 is provided to the casing 3. The connector cap 17 exposes from the opening 3s. The connector cap 17 is fixed to the wall portion 3t at an inside position of the opening 3s. The connector cap 17 decreases a clearance between the external connector 100 attached to the connector 11A and the casing 3. The connector cap 17 is formed in a substantially plate-like shape. The connector cap 17 is provided with a convex portion 17a (a restriction portion, a projecting portion, a protruding portion, an abutting portion). That is, the convex portion 17a is provided to the casing 3. The convex portion 17a protrudes from a surface 17b on the connector 11A side of the connector cap 17 toward the base portion 11a of the connector 11A. The convex portion 17a is integrally formed with the connector cap 17. The convex portion 17a is positioned at the side of the connector 11A opposite to the elastic member 16. The convex portion 17a restricts the movement of the connector 11A. To be more specific, the convex portion 17a abuts on the side of the base portion 11a of the connector 11A opposite to the elastic member 16. The convex portion 17a abuts on the connector 11A (the base portion 11a) to restrict the movement of the connector 11A. The base portion 11a of the connector 11A is sandwiched between the convex portion 17a and the elastic member 16. The convex portion 17a and the connector cap 17 can be, as an example, formed of a resin material. Furthermore, the convex portion 17a and the connector cap 17 can be, as an example, formed of a conductive metallic material. Due to such a constitution, the convex portion 17a and the connector cap 17 can establish a ground for the connector 11A. The material of the convex portion 17a and the connector cap 17 are higher in Young's modulus than the material of the elastic member 16. As an example, the convex portion 17a is rigid. Here, although the example that the convex portion 17a is provided in a state that the convex portion 17a abuts on the connector 11A is explained, the present embodiment is not limited thereto. As another example, the convex portion 17a is provided in a state that the convex portion 17a is spaced apart from the connector 11A. For example, when vibrations or an impact is applied to the casing 3, the convex portion 17a may be brought into contact with the connector 11A moved to prevent the connector 11A from being moved further.

As explained heretofore, in the present embodiment, the elastic member 16 is positioned between the connector 11A and the casing 3 and abuts on the connector 11A. The convex portion 17a is positioned at the side of the connector 11A opposite to the elastic member 16 so as to abut on the connector 11A thus restricting the movement of the connector 11A. Therefore, the movement of the connector 11A elastically supported on the elastic member 16 is restricted by the convex portion 17a that abuts on the connector 11A thus preventing the connector 11A from being displaced.

Here, when the displacement of the connector 11A is increased, there exists a possibility that it becomes difficult to sufficiently ensure the space S into which the external connector 100 is inserted. However, in the present embodiment, the convex portion 17a restricts the displacement of the connector 11A thus sufficiently ensuring the space S into which the external connector 100 is inserted around the attachment portion 11b of the connector 11A. Consequently, according to the present embodiment, it is possible to attach the external connector 100 to the connector 11A successfully.

Furthermore, if the displacement of the connector 11A becomes larger, the load acting on the board 6 on which the connector 11A is mounted becomes heavier. In the present embodiment, the convex portion 17a restricts the displacement of the connector 11A thus preventing the load applied to the board 6 by the connector 11A from being increased. Accordingly, it is possible to prevent the board 6 from being deformed (inclined).

In the present embodiment, the convex portion 17a restricts the movement of the connector 11A, and a contact pressure between the connector 11A and the elastic member 16 is increased thus improving conductive efficiency between the connector 11A and the elastic member 16.

Furthermore, in the present embodiment, the convex portion 17a as a restriction portion is provided to the connector cap 17, and it is unnecessary to provide a part only for the restriction portion thus suppressing the increase of the number of parts of the television receiver.

Here, in the present embodiment, the example that the connector 11A is sandwiched between the elastic member 16 and the convex portion 17a (the restriction portion) is explained. However, a part sandwiched between the elastic member 16 and the convex portion 17a (the restriction portion) is not limited to the connector 11A. For example, as a part sandwiched between the elastic member 16 and the convex portion 17a (the restriction portion), a speaker, a microphone, or a camera may also be adopted.

Next, a first modification of the present embodiment will be explained in conjunction with FIG. 4. In the present modification, a restriction portion is not provided to the connector cap 17 but provided to the connector 11A. As an example, a convex portion 11c as a restriction portion is provided to the outer surface of the base portion 11a. The convex portion 11c abuts on the connector cap 17 of the casing 3 to restrict the movement of the connector 11A.

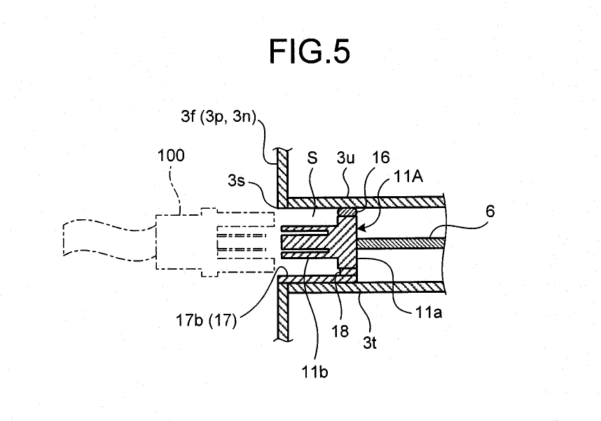

Next, a second modification of the present embodiment will be explained in conjunction with FIG. 5. In the present modification, a restriction part 18 (a spacer) as the restriction portion is provided as a part other than the connector cap 17 and the connector 11A. The restriction part 18 is, as an example, formed in a plate-like shape. The restriction part 18 abuts, as an example, on the connector cap 17 of the casing 3 and the connector 11A. The restriction part 18 may be, as an example, fixed to at least one of the connector cap 17 and the connector 11A. Furthermore, the restriction part 18 may be, as an example, supported by being sandwiched between the connector cap 17 and the connector 11A.

### Second Embodiment

In the present embodiment, as an example, an electronic device 1A is provided with a first casing 3A and a second casing 2A. To be more specific, the first casing 3A (the first part) houses at least one portion of a display 4. The second casing 2A houses a board 6A. The second casing 2A is provided with a keyboard 7 (an input operation module, a first input operation module, an input reception module, an input module), a pointing device 8a (an input operation module, a second input operation module, an input reception module, an input module), and click buttons 8b (input operation modules, third input operation modules, input reception modules, input modules), for example.

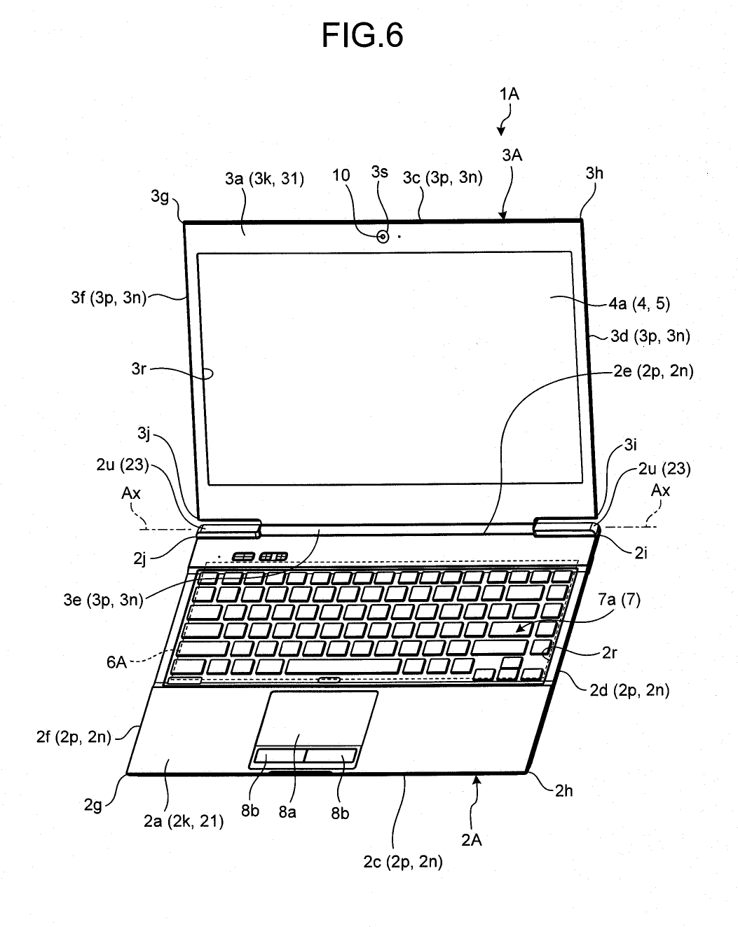

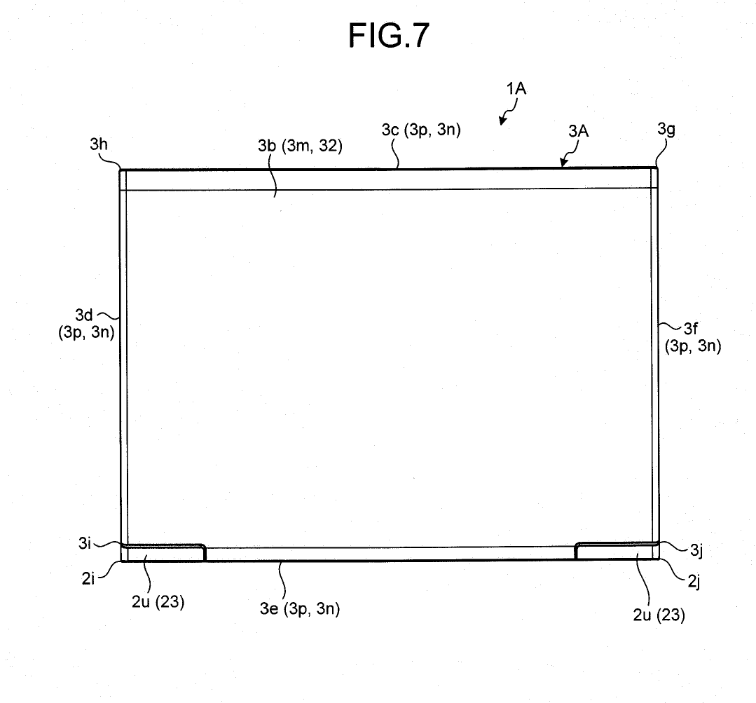

The first casing 3A and the second casing 2A are connected with each other in a rotatable manner by means of a hinge part (a connection part, a joining part, a rotatably supporting part, a hinge mechanism, a connection mechanism, a joining mechanism, a rotatably supporting mechanism). The first casing 3A and the second casing 2A are connected with each other in a manner such that the first casing 3A and the second casing 2A are rotatable relative to each other within a range between at least an open state illustrated in FIG. 6 and a folded state illustrated in FIG. 7. In the present embodiment, as an example, the hinge part connects the first casing 3A and the second casing 2A in a manner such that the first casing 3A and the second casing 2A are rotatable relative to each other about a rotational axis Ax. The screen 4a of the display 4 is exposed from an opening 3r provided to the surface 3a (the anterior face, the front face, the first surface, the first surface portion) of the first casing 3A. Furthermore, the keyboard 7, the pointing device 8a, and the click buttons 8b, for example, are exposed on a surface 2a (the top surface, the front face, the first surface, the first surface portion) of the second casing 2A. In the folded state, the surface 3a of the first casing 3A and the surface 2a of the second casing 2A are overlapped with each other, and the screen 4a, the keyboard 7, the pointing device 8a, and the click buttons 8b, for example, are hidden by the first casing 3A and the second casing 2A. In the open state, the surface 3a of the first casing 3A and the surface 2a of the second casing 2A are exposed, and the screen 4a, the keyboard 7, the pointing device 8a, and the click buttons 8b, for example, become usable (viewable or operational).

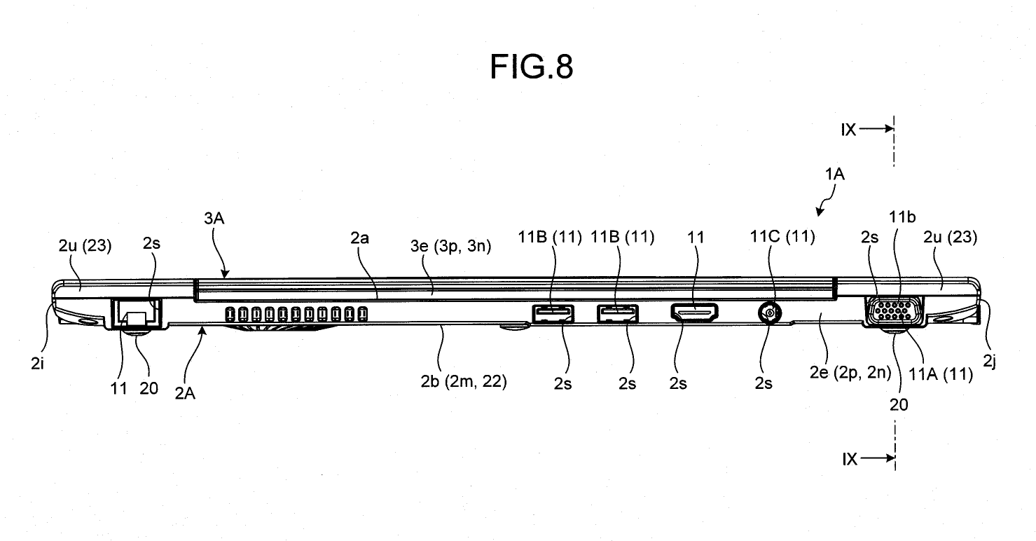

In the present embodiment, the first casing 3A is, as an example illustrated in FIGS. 6 and 7, formed in a quadrangular shape (rectangular shape, as an example in the present embodiment) as viewed in a front view and in a rear view. In the present embodiment, the first casing 3A is, as an example illustrated in FIG. 8, formed in a flat rectangular parallelepiped shape with a small thickness in the front-back direction. The first casing 3A comprises the surface 3a (the anterior face, the front face, the first surface, the first surface portion) and the surface 3b (a back surface, a rear face, a second surface, a second surface portion) opposite to the surface 3a. The surface 3a and the surface 3b are arranged substantially parallel to each other. Furthermore, the first casing 3A comprises, as illustrated in FIG. 6, four end portions 3c to 3f (side portions, edge portions) and four corner portions 3g to 3j (convex portions, bent portions, end portions). Each of the end portions 3c and 3e is an example of a width side portion. Each of the end portions 3d and 3f is an example of a length side portion.

Furthermore, the first casing 3A comprises the wall portion 3k (a first portion, a plate, a frame, an anterior wall portion, a front wall portion, a top wall portion) comprising the surface 3a and the wall portion 3m (a second portion, a plate, a rear wall portion, a back wall portion, a bottom wall portion) comprising the surface 3b. The wall portions 3k and 3m are formed in a quadrangular shape (a rectangular shape, as an example in the present embodiment). Furthermore, the first casing 3A comprises four wall portions 3n (third portions, plates, side wall portions, end wall portions, erected wall portions, connecting portions) comprising surfaces 3p (side surfaces, peripheral surfaces, third surfaces) each of which extends between the wall portion 3k and the wall portion 3m. Here, the wall portion 3k is, as an example, provided with the opening 3r formed in a quadrangular shape. Accordingly, the wall portion 3k is formed in a quadrangular shape and in a frame shape.

In addition, the first casing 3A can be constituted of a plurality of parts (separated bodies) combined with each other. In the present embodiment, the first casing 3A comprises, as an example, the first casing member 31 (a first portion, a front side member, a mask, a mask portion, a cover, a front cover, a cover portion, a first region) comprising at least the wall portions 3k and the second casing member 32 (a second portion, a rear side member, a base, a base portion, a bottom, a bottom portion, a cover, a rear cover, a cover portion, a second region) comprising at least the wall portions 3m. The wall portions 3n are comprised in at least any one of the first casing member 31 and the second casing member 32 (the second casing member 32, for example). Furthermore, the first casing 3A can comprise, in addition to the first casing member 31 and the second casing member 32, a third casing member (a third portion, an intermediate portion, a spacer member, a barrier member, a wall member, an interjacent member, an inner plate, a middle plate, a middle frame, a third region, not illustrated in the drawings), a fourth casing member (a fourth portion, an intermediate portion, a spacer member, a barrier member, a wall member, an interjacent member, a cover, a shield, a fourth region, not illustrated in the drawings), or other members that are positioned therebetween.

The first casing 3A can be made of metallic, synthetic-resin, or other material. The first casing member 31 and the second casing member 32 can be made of a material being comparatively low in rigidity (a material being lower in rigidity than that of the third casing member or the fourth casing member; that is, a synthetic-resin material, for example). Here, wall portions such as ribs (protruding portions, protruding wall portions, not illustrated in the drawings) can be provided to surfaces of the first casing member 31 and the second casing member 32, the surfaces facing inside the first casing 3A. The wall portions easily increase the rigidity of the first casing 3A.

In the present embodiment, as an example illustrated in FIG. 6, the surface 3a of the first casing 3A can be provided with the camera module 10 (a camera, an image pickup device). The camera module 10, for example, is exposed through the opening 3s provided to the wall portion 3k of the first casing 3A. Here, the surface 3p of the first casing 3A can be provided with connectors or operation modules.

In the present embodiment, as an example illustrated in FIG. 6, the screen 4a positioned at the surface 3a side of the display 4 (the display part, the display, the display panel) is exposed toward the front side (outside) of the first casing 3A through the opening 3r. A user can view the screen 4a through the opening 3r from the front side of the first casing 3A. The display 4 is formed in a quadrangular shape (a rectangular shape, as an example in the present embodiment) as viewed in a front view. Furthermore, the display 4 is formed in a flat rectangular parallelepiped shape with a small thickness in the front-back direction. The display 4 is, for example, constituted of a liquid crystal display (LCD), an organic electro-luminescent display (OELD), or the like.

In the present embodiment, as an example, the display 4 provides an input operation panel 5 (a touch panel, a touch sensor, or an operation panel, as an example) to the front side (the anterior side, the wall portion 3k side) thereof. The input operation panel 5 is formed in a transparent flat rectangular parallelepiped shape with a comparatively small thickness and covers the screen 4a. An operator (a user, for example) performs, for example, operations of touching, pushing, or rubbing the input operation panel 5 by using a finger or a tool (a stylus or the like, not illustrated in the drawings), or operations of moving the finger or the stylus in the vicinity of the input operation panel 5 thus performing input processing. Furthermore, light emitted from the screen 4a of the display 4 passes through the input operation panel 5 and goes out from the opening 3r toward the front side (outside) of the first casing 3A. The input operation panel 5 is an example of an input module.

In the present embodiment, the second casing 2A is, as an example illustrated in FIGS. 6 and 7, formed in a quadrangular shape (rectangular shape, as an example in the present embodiment) as viewed in a front view and in a rear view. In the present embodiment, the second casing 2A is, as an example illustrated in FIG. 8, formed in a flat rectangular parallelepiped shape with a small thickness in the front-back direction. The second casing 2A comprises the surface 2a (the top surface, the front face, the first surface, the first surface portion) and a surface 2b (a bottom surface, a rear face, a second surface, a second surface portion) opposite to the surface 2a. The surface 2a and the surface 2b are arranged substantially parallel to each other. Furthermore, the second casing 2A comprises, as illustrated in FIG. 6, four end portions 2c to 2f (side portions, edge portions) and four corner portions 2g to 2j (convex portions, bent portions, end portions) as viewed in a front view. Each of the end portions 2c and 2e is an example of a width side portion. Each of the end portions 2d and 2f is an example of a length side portion.

The second casing 2A comprises a wall portion 2k (a first portion, a plate, a frame, an anterior wall portion, a front wall portion, a top wall portion) comprising the surface 2a and a wall portion 2m (a second portion, a plate, a rear wall portion, a back wall portion, a bottom wall portion, see FIG. 8) comprising the surface 2b. The wall portions 2k and 2m are formed in a quadrangular shape (a rectangular shape, as an example in the present embodiment). Furthermore, the second casing 2A comprises four wall portions 2n (third portions, plates, side wall portions, end wall portions, erected wall portions, connecting portions) comprising surfaces 2p (side surfaces, peripheral surfaces, third surfaces) each of which extends between the wall portion 2k and the wall portion 2m. Here, the wall portion 2k is, as an example, provided with an opening 2r formed in a quadrangular shape. Accordingly, the wall portion 2k is formed in a quadrangular shape and in a frame shape.

In addition, the second casing 2A can be constituted of a plurality of parts (separated bodies) combined with each other. In the present embodiment, the second casing 2A comprises, as an example, a first casing member 21 (a first portion, a front side member, a mask, a mask portion, a cover, a front cover, a cover portion, a first region, see FIG. 6) comprising at least the wall portion 2k and a second casing member 22 (a second portion, a rear side member, a base, a base portion, a bottom, a bottom portion, a cover, a rear cover, a cover portion, a second region, see FIG. 8) comprising at least the wall portion 2m. The wall portions 2n are comprised in at least any one of the first casing member 21 and the second casing member 22 (the second casing member 22, for example). Furthermore, the second casing 2A can comprise, in addition to the first casing member 21 and the second casing member 22, a third casing member (a third portion, an intermediate portion, a spacer member, a barrier member, a wall member, an interjacent member, an inner plate, a middle plate, a middle frame, a third region, not illustrated in the drawings), a fourth casing member (a fourth portion, an intermediate portion, a spacer member, a barrier member, a wall member, an interjacent member, a cover, a shield, a fourth region, not illustrated in the drawings), or other members that are positioned therebetween.

The second casing 2A can be made of metallic, synthetic-resin, or other material. The first casing member 21 and the second casing member 22 can be made of a material being comparatively low in rigidity (a material being lower in rigidity than that of the third casing member or the fourth casing member; that is, a synthetic-resin material, for example). Here, wall portions such as ribs (protruding portions, protruding wall portions, not illustrated in the drawings) can be provided to surfaces of the first casing member 21 and the second casing member 22, the surfaces facing inside the second casing 2A. The wall portions easily increase the rigidity of the second casing 2A.

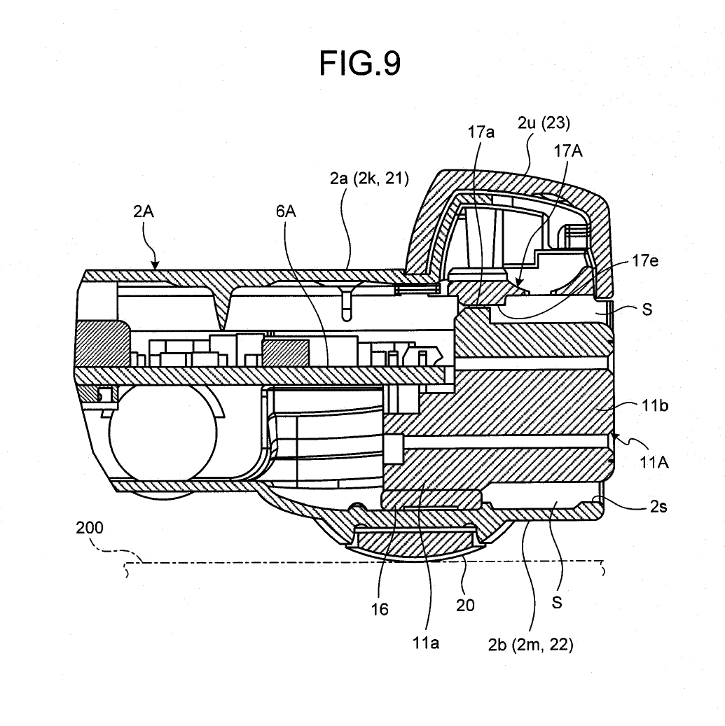

The wall portion 2m of the second casing 2A is provided with supports 20 (foot portions, feet, rubber members) supporting the second casing 2A. Each of the supports 20 is, as an example, provided to each of the four corner portions 2g to 2j. The supports 20 protrude from the surface 2b. The support 20 is, as an example, constituted of an elastic member made of rubber or other material. The supports 20 are placed on an external placing surface 200 (FIG. 9). The supports 20 support the second casing 2A in a state that the supports 20 are placed on the external placing surface 200 (FIG. 9).

In the present embodiment, as an example illustrated in FIG. 8, the surface 2p or other portions of the second casing 2A can be provided with connectors 11 or the like. Examples of the connectors 11 include the connector 11A for data communication, the universal serial bus (USB) connector 11B, a connector 11C for a power cable, a card connector, and a connector for an earphone or a microphone. The connectors 11 are exposed through openings provided to the wall portion 2n of the second casing 2A. Here, the surface 2a of the second casing 2A can be provided with connectors or operation modules.

Furthermore, in the present embodiment, as an example illustrated in FIG. 6, an operation panel 7a (a face, a top face) of the keyboard 7 is exposed toward the front side (outside) of the second casing 2A through the opening 2r. On the surface 2a, the keyboard 7 is positioned at a side close to the end portion 2e, and the pointing device 8a and the click buttons 8b are arranged on a side close to the end portion 2c opposite to the end portion 2e. The end portion 2e is positioned at a back side of the surface 2a in the horizontal depth direction (the front-back direction) and the end portion 2c is positioned at a near side of the surface 2a in the same direction as above.

In the present embodiment, as an example illustrated in FIG. 6, the second casing 2A houses therein one or more boards 6A (a circuit board, a control board, a main board, an electric component, a first electric component) on the rear side (the back side, the behind side, the wall portion 2m side, a side opposite to the operation panel 7a) of the keyboard 7. The board 6A is provided parallel to the keyboard 7. The board 6A is provided in a state that the board 6A is spaced apart from the wall portions 2k, 2m, and 2n, for example; that is, in a state that a space (a clearance) is formed between the board 6A and the wall portions 2k, 2m, and 2n, for example.

In the present embodiment, as an example, the board 6A can, for example, mount thereon a plurality of parts (not illustrated in the drawings) such as a central processing unit (CPU), a graphics controller, a power circuit component, a platform controller hub (PCH), a memory slot connector, an LCD connector, an input/output (I/O) connector, a power supply coil, an element, or a connector. The board 6 mounts a connector 11A for data communication thereon. Furthermore, a control circuit can, for example, comprise a video signal processing circuit, a tuner, a high-definition multi media interface (HDMI) signal processing module, an audio video (AV) input terminal, a remote control signal receiving module, a control module, a selector, an onscreen display interface, a storage (a read only memory (ROM), a random access memory (RAM), a hard disk drive (HDD), or a solid state drive (SSD), for example), an audio signal processing circuit, for example. The control circuit controls the output of videos (moving pictures, still pictures, for example) on the screen 4a of the display 4, the output of sounds by a speaker (not illustrated in the drawings), the emission of light from a light emitting diode (LED, not illustrated in the drawings), for example. The display 4, the speaker, and the LED, are examples of an output module.

Furthermore, in the present embodiment, as an example illustrated in FIGS. 6 and 7, the end portion 2e of the second casing 2A provides protruding portions 2u protruding from the surface 2a in the thickness direction on the both ends thereof in the longitudinal direction. In the present embodiment, as an example illustrated in FIGS. 7 and 8, each of the protruding portions 2u houses a part of the hinge part (apart on the second casing 2A side) therein. In the present embodiment, as an example illustrated in FIG. 8, the connector 11A that is larger in height (thickness) than the other connectors 11 is provided corresponding to the protruding portion. In the present embodiment, as an example, the protruding portion 2u provides therein the hinge part adjacent to the connector 11. Furthermore, as illustrated in FIG. 8, the protruding portion 2u provides therein a hinge cap 23 adjacent to the connector 11. Therefore, as an example, the height (thickness) of the electronic apparatus 1A at a portion to which the connector 11 being large in height (thickness) is provided is easily reduced compared with a case that the wall portion of the second casing 2A is provided between the connector 11 and the hinge part or between the connector 11 and the hinge cap 23. Furthermore, the protruding portion 2u in which the hinge part is housed is covered with the hinge cap 23 (the cover, the cap, the cover part, the cover, the fifth casing member) other than the first casing member 21 and the second casing member 22 thus easily separating, as an example, a process for assembling (attaching, handling) the first casing member 21 or the second casing member 22 from a process for assembling (attaching, handling) parts around the hinge part (the hinge part, the connector 11A, and a harness, for example). Therefore, as an example, time and efforts for manufacturing thereof can be easily reduced. Furthermore, as an example, the surface (outer surface) of the hinge cap 23 is decorated by a treatment, such that the hinge cap 23 is, for example, coated with a metallic coating material, different from that applied to the other portions (the general portions, the first casing members 21 and 31, the second casing members 22 and 32, for example) thus giving an accent to the external appearance of the electronic apparatus 1A.

As an example illustrated in FIG. 9, the connector 11A is arranged between the wall portion 2m (the first wall portion) and the wall portion 2k (the second wall portion) of the second casing 2A, and exposed from the opening 2s. The connector 11A comprises, as illustrated in FIGS. 9 to 11, the base portion 11a and the attachment portion 11b in the same manner as the case of the first embodiment. The base portion 11a is, as an example, formed in a substantially rectangular parallelepiped shape. The base portion 11a is housed in the inside of the casing 3. The attachment portion 11b projects from the base portion 11a toward the outside of the second casing 2A. The attachment portion 11b extends from the base portion 11a toward the opening 2s. In the connector 11A, an external connector 100 (see FIG. 5) is attached to the attachment portion 11b. The space S for inserting the external connector 100 is formed around the attachment portion 11b.

In between the connector 11A and the wall portion 2m, an elastic member 16 (an elastic part, a gasket, FIG. 9) is positioned. The elastic member 16 has elasticity. The elastic member 16 is, as an example, adhered (fixed) to the wall portion 2m by bonding, for example. The elastic member 16 abuts on the base portion 11a of the connector 11A to elastically support the connector 11A. Furthermore, the elastic member 16 is made of a conductive material. The elastic member 16 connects the connector 11A and the wall portion 2m electrically to establish a ground for the connector 11A.

Furthermore, a connector cap 17A (a cover, a part, a cap) is provided to the side of the connector 11A opposite to the elastic member 16. The connector cap 17A constitutes a part of the second casing 2A. At least a part of the connector cap 17A is positioned at the side of the connector 11A opposite to the elastic member 16 and covers a part of the connector 11A. The connector cap 17A is provided to the second casing 2A. The connector cap 17 is exposed from the opening 2s. The connector cap 17A is fixed to the wall portion 2k. The connector cap 17A is, as an example, fixed to a support 2q (FIG. 13) provided to the wall portion 2k. The support 2q provides thereto a plurality of pins 2t and ribs 2v. The connector cap 17A decreases a clearance between the external connector 100 attached to the connector 11A and the hinge cap 23.

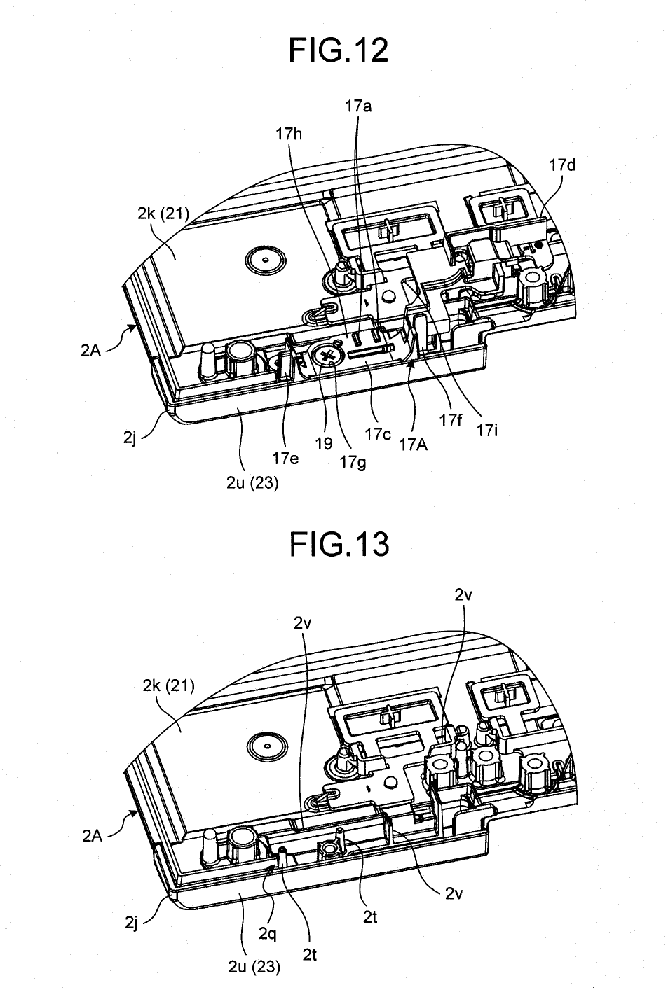

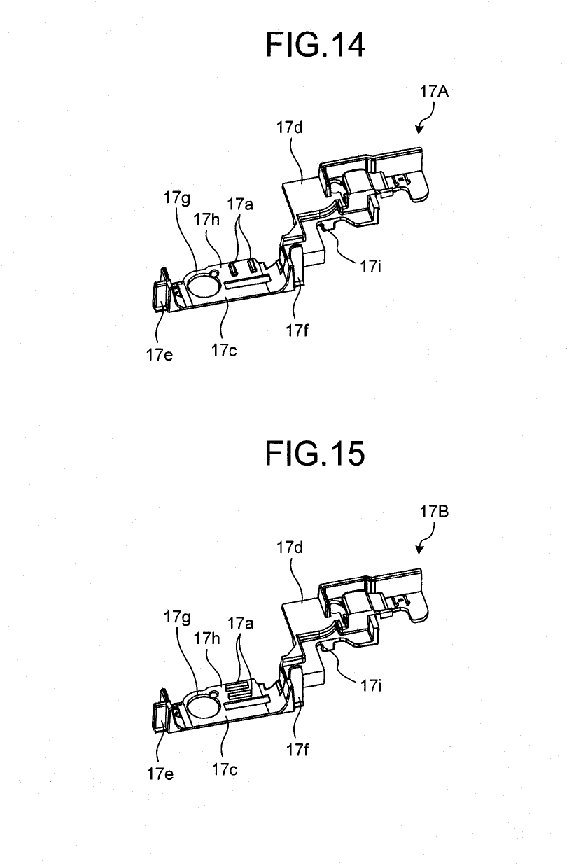

The connector cap 17A comprises, as illustrated in FIGS. 12 and 14, a base portion 17c (a portion, a first portion) overlapped with the connector 11A and an projecting portion 17d (a portion m, a second portion) projecting from the base portion 17c. The base portion 17c comprises a pair of end portions 17e and 17f. The end portions 17e and 17f are fixed to the wall portion 2k by bonding or fastening. The base portion 17c is provided with an opening 17g (FIG. 14) into which a fastener 19 (a screw, FIG. 12) is inserted.

The connector cap 17A is, as illustrated in FIG. 14, provided with convex portions 17a (a restriction portion, a projecting portion, a protruding portion, an abutting portion). That is, the convex portions 17a are provided to the second casing 2A. There are two convex portions 17a provided between a pair of the end portions 17e and 17f. The convex portion 17a is formed in a substantially rectangular parallelepiped shape. The convex portion 17a is provided in an extending manner along the direction substantially orthogonal to the direction of connecting the end portions 17e and 17f. The convex portions 17a protrude from a surface 17h on the connector 11A side of the base portion 17c of the connector cap 17A toward the base portion 11a of the connector 11A. The convex portions 17a are integrally formed with the connector cap 17. The convex portions 17a are positioned at the side of the connector 11A opposite to the elastic member 16. The convex portions 17a restrict the movement of the connector 11A. To be more specific, the convex portions 17a abut on the side of the base portion 11a of the connector 11A opposite to the elastic member 16. The convex portions 17a abut on the connector 11A (the base portion 11a) so as to restrict the movement of the connector 11A. The base portion 11a of the connector 11A is sandwiched between the convex portions 17a and the elastic member 16. The convex portions 17a and the connector cap 17A can be, as an example, made of resin material. Furthermore, the convex portions 17a and the connector cap 17A can be, as an example, made of conductive metallic material. Due to such a constitution, the convex portions 17a and the connector cap 17A can establish a ground for the connector 11A. The material of the convex portion 17a and the connector cap 17A are higher in Young's modulus than that of the elastic member 16. As an example, the convex portion 17a is rigid. Here, the positional relationship between the connector cap 17A and the elastic member 16 may be made in reverse to that illustrated in FIG. 9.

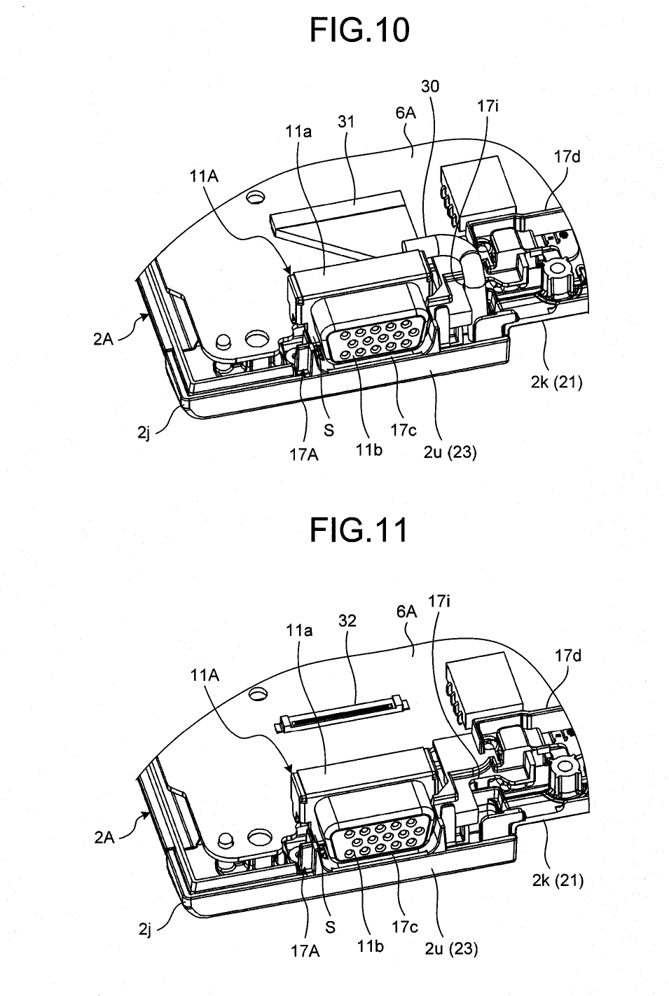

In the present embodiment, as an example illustrated in FIGS. 10 and 14, the connector cap 17 is provided with a guide portion 17i that guides (supports) a harness 30 (wiring, FIG. 10). The guide portion 17i is, as an example, provided to the projecting portion 17d. The end portion of the harness 30 is provided with a connector 31 (FIG. 10). The connector 31 is inserted into a connector 32 (FIG. 11) mounted on the board 6A. The harness 30 connects, for example, the board 6A (the electric parts, the circuits) in the casing 3 and electric parts (a display, a speaker, and a camera, for example). Furthermore, the connector cap 17 also functions as a cover for covering a part of the harness 30.

Furthermore, in the present embodiment, as an example illustrated in FIGS. 8 and 9, the connector 11A is located at a position such that the connector 11A is overlapped with the support 20 (the support 20 at the corner portion 2j) above the support 20 (the support 20 at the corner portion 2j) when the support 20 (the support 20 at the corner portion 2j) is placed on the external placing surface 200. In the present embodiment, the convex portion 17a is, as illustrated in FIG. 9, located at a position such that the convex portion 17a is overlapped with the support 20 (the support 20 at the corner portion 2j) above the support 20 (the support 20 at the corner portion 2j) when the support 20 (the support 20 at the corner portion 2j) is placed on the external placing surface 200. Due to such a constitution, at least a part of a load applied to the support 20 is applied to the wall portion 2k via the elastic member 16, the connector 11A, and the convex portion 17a, for example, thus preventing the load being applied to the board 6A.

As explained heretofore, in the present embodiment, the elastic member 16 is positioned between the connector 11A and the second casing 2A and abuts on the connector 11A. The convex portion 17a is positioned at the side of the connector 11A opposite to the elastic member 16 and abuts on the connector 11A thus restricting the movement of the connector 11A. Therefore, the convex portion 17a abutting on the connector 11 restricts the movement of the connector 11A elastically supported by the elastic member 16 thus preventing the connector 11A from being displaced.

Next, a modification of the present embodiment will be explained in conjunction with FIG. 15. In a connector cap 17B of the present modification, the convex portion 17a is provided in an extending manner along the direction of connecting the end portions 17e and 17f. Due to such a constitution, it is possible to improve flexural rigidity provided between the end portions 17e and 17f.

As explained heretofore, according to the above-mentioned respective embodiments, it is possible to prevent the connector 11A from being displaced.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television receiver comprising:
a display;
a casing comprising an opening, the casing being configured to house the display;
a board configured to be housed in the casing;
a connector configured to be mounted on the board and exposed from the opening;
an elastic member between the connector and the casing, the elastic member being configured to touch the connector;
a cover configured to be at least partially positioned at a side of the connector opposite to the elastic member and cover a part of the connector; and
a restriction portion configured to be positioned at the side of the connector opposite to the elastic member and restrict movement of the connector.

2. The television receiver of claim 1, wherein the restriction portion is on, at, or near the cover and is configured to touch the connector to restrict the movement of the connector.

3. The television receiver of claim 2, wherein
the cover is configured to be exposed from the opening, and
the restriction portion comprises a convex portion.

4. The television receiver of claim 1, wherein
the connector comprises a base portion and an attachment portion projecting from the base portion toward the outside of the casing, the attachment portion being configured to be attached to an external connector,
the elastic member is configured to touch the base portion, and
the restriction portion is configured to touch a side of the base portion opposite to the elastic member.

5. The television receiver of claim 1, wherein the restriction portion comprises a convex portion on, at, or near the connector and is configured to touch the cover to restrict the movement of the connector.

6. The television receiver of claim 5, wherein
the connector comprises a base portion and an attachment portion projecting from the base portion toward the outside of the casing, the attachment portion being configured to be attached to an external connector, and
the restriction portion is provided to the base portion and is configured to touch the cover to restrict the movement of the connector.

7. The television receiver of claim 1, further comprising:
a support configured to be on, at, or near the casing and placed on an external placing surface, wherein
the connector is located at a position such that the connector is overlapped with the support above the support when the support is placed on the external placing surface.

8. The television receiver of claim 7, wherein the restriction portion is located at a position such that the restriction portion is overlapped with the support above the support when the support is placed on the external placing surface.

9. The television receiver of claim 1, wherein the restriction portion has a conductivity.

10. An electronic device comprising:
a casing comprising an opening;
a board configured to be housed in the casing;
a connector configured to be mounted on the board and exposed from the opening;
an elastic member between the connector and the casing, the elastic member being configured to touch the connector;
a cover configured to be at least partially positioned at a side of the connector opposite to the elastic member and cover a part of the connector; and
a restriction part configured to be positioned at the side of the connector opposite to the elastic member and restrict movement of the connector.
